(19) United States
(12) Patent Application Publication
(10) Pub. No.: US 2007/0109571 A1
(43) Pub. Date: May 17, 2007

(54) COLOR FILTER WITH COLOR CONVERSION FUNCTION, PRODUCING METHOD THEREOF, AND ORGANIC EL DISPLAY

(75) Inventor: Yukinori KAWAMURA, Hino-shi, Tokyo (JP)

Correspondence Address: ROSSI, KIMMS & McDOWELL LLP., P.O. BOX 826, ASHBURN, VA, 20146-0826, US

(73) Assignee: FUJI ELECTRIC HOLDINGS CO.,LTD, Kawasaki-ku (JP)

(21) Appl. No.: 11/557,197

(22) Filed: Nov. 7, 2006

(30) Foreign Application Priority Data
Nov. 15, 2005 (JP) 2005-330290
Apr. 5, 2006 (JP) 2006-103800

(51) Int. Cl. G03F 3/08

(52) U.S. Cl. 358/1.9; 358/518

(57) ABSTRACT

A filter and a display employing a color conversion mode that can simplify production, achieve high definition patterning, and enhance color conversion efficiency for every primary color is disclosed. A color filter with color conversion function includes a transparent substrate, a plurality types of color filter layers disposed on the transparent substrate, and a color conversion layer containing at least one color conversion material and disposed in one-piece over the color filter layers. At least one of the color conversion materials absorbs a wavelength region of incident light and emits light in different wavelength region from the absorbed wavelength region, and a region in the color conversion layer of passage of the incident light to one color filter layer exhibits higher light transmissivity to the incident light than regions in the color conversion layer of passage of the incident light to the other color filter layers.

### CROSS REFERENCE TO RELATED APPLICATIONS

This application is based on, and claims priority to, Japanese Patent Application No. 2005-330290, filed on Nov. 15, 2005 and Japanese Patent Application No. 2006-103800, filed on Apr. 5, 2006, the entire contents of which are incorporated herein by reference.

### BACKGROUND OF THE INVENTION

1. Field of the Invention

The present invention relates to a color filter with color conversion function capable of multicolor display, a method of manufacturing the color filter, and an organic EL display. The color filter with color conversion function can be applied to image sensors, personal computers, word processors, televisions, facsimiles, audio equipment, video recorders, car navigation, electronic calculators, telephones, mobile terminals, and industrial instruments.

2. Description of the Related Art

For multicolor or full color display, color conversion systems which use a filter containing color conversion materials that absorbs light in the near-ultraviolet, blue color, blue-green color, or white color, changes the wavelength distribution of the light, and emits light in the visible light range recently have been studied (Japanese Patent Unexamined Publication Nos. H08-279394 and H08-286033). Since the color emitted by a light source is not limited to white in the color conversions system, a light source can be selected more freely. For example, an organic light emitting device emitting blue color light can be used to obtain green and red color light after changing the wavelength distribution. (Japanese Patent Unexamined Publication No. H09-204982 and Mat. Res. Soc. Symp. Proc., Vol. 708, P. 145-150, (2002)). Thus, the possibility of constructing a display that allows use of a light source of higher efficiency, and provides a full color, self-light-emitting display using only a light energy line in the range of near-ultraviolet to visible light has been studied (Japanese Patent Unexamined Publication No. H09-80434).

Major practical problems in color displays include provision of a color conversion filter exhibiting high color conversion efficiency, in addition to definite color display performance and long term stability including reproducibility. However, if a concentration of the color conversion material is increased in order to increase color conversion efficiency, the efficiency decreases due to so-called concentration quenching, and decomposition of the color conversion material occurs with the passage of time. To cope with this problem, the thickness of a color conversion layer containing the color conversion material is increased to obtain a desired color conversion efficiency in prior art. To avoid the concentration quenching and decomposition of color conversion materials, studies have been made in which a bulky substituent is introduced into a core of the color conversion material (Japanese Patent Unexamined Publication Nos. H 1-279426, 2000-44824 and 2001-164245). Mixing of a quencher has also been studied for preventing the color conversion material from decomposing (Japanese Patent Unexamined Publication No. 2002-231450).

WO97/43874 and Japanese Patent Unexamined Publication No. 2001-131434 disclose an organic EL device that makes use of photo-bleaching. The technique disclosed in these documents uses organic dyestuffs that can become at least two types of light emitting centers. In the process of producing the organic EL device, an organic light emitting dye layer is partly illuminated by electromagnetic waves (light) to bleach at least one type of the dyestuff through photochemical oxidation or photochemical decomposition, thereby converting the doped dyestuffs into a condition in which they do not work or work insufficiently as a light emitting center. As a result, the color of the emitted light is changed. The color of the emitted light from the illuminated parts becomes different from the color of the emitted light from the non-illuminated parts.

The essential point of this technique is to control energy transfer from excitons in the host material in the organic light emitting layer as described in the following. An exciton is generated on recombination of a hole and an electron, which are injected from an anode and a cathode, in the host material of the light emitting layer of the organic EL device. When a dopant dye having a lower excitation energy level than that of the host material exists in the light emitting layer, energy is transferred from the exciton to the dopant, changing the color of the emitted light. The above-described technique of the prior art forms a light emitting layer containing a plurality of the dopant dyestuffs, and then the dopant is made ineffective by partial light illumination, changing the color of emitted light. Thus, a multicolor organic EL display is constructed.

In order to obtain a high definition multicolor or full color display employing a color conversion system, the color conversion layer must be patterned very precisely. However, in a case of patterning having a width smaller than a film thickness, for example, problems of reproducibility of a pattern shape and distortion of the pattern in the subsequent processes may arise. In addition, patterning by a normal photolithography needs an applying step, an exposure step accompanying mask alignment, and a development step for each color of color conversion layer. A full color display needs at least a red, green, and blue color conversion layers. So, a procedure of producing the full color display requires multiple steps and is rather complicated. In producing a multicolor or full color display employing a color conversion system, improvement in color conversion efficiency for each primary color (for example RGB) has always been one of the most important problems.

In order to obtain light of three primary colors from each pixel in a prior art technique using photo-bleaching, dopants are preliminarily doped in the light emitting layer to obtain light emission in the three colors including the color from the host material. After forming the light emitting layer, light matching the absorption wave length of each dyestuff is needed to illuminate each pixel so as to selectively oxidize the pixel photochemically. If the absorption bands of the dopant dyestuffs are close to each other or overlapping, insufficient separation results. Therefore, selection of the dyestuffs is difficult. Further, a filter must be inserted in front of the illuminating light source to adjust wavelength of the light.

The present invention is directed to overcoming or at least reducing the effects of one or more of the problems set forth above.

### SUMMARY OF THE INVENTION

It is therefore an object of the present invention to provide a color conversion filter and a method for producing it that allows simplified production procedure and high definition patterning, and improves color conversion efficiency for the primary colors.

According to one aspect of the present invention, a color filter with color conversion function is provided that comprises a transparent substrate, plural types of color filter layers disposed on the transparent substrate, and a color conversion layer containing at least one color conversion material and disposed in one-piece over the color filter layers, wherein at least one of the color conversion materials absorbs a wavelength region of incident light and emits light in a different wavelength region from the absorbed wavelength region, and a region in the color conversion layer of passage of the incident light towards one color filter layer exhibits higher light transmissivity to the incident light than regions in the color conversion layer of passage of the incident light towards the other color filter layers.

Preferably, at least a portion of the color conversion materials in the region of passage of incident light exhibiting higher light transmissivity is photo-bleached. The color conversion layer is preferably formed in one-piece covering the color filter layers. Preferably, the incident light to the color conversion layer is light in blue to blue-green color region, and at least one of the color conversion materials emits light having a spectrum containing a red color region. The plural types of color filter layers are favorably a red color filter layer, a green color filter layer, and a blue color filter layer, and preferably a region of passage of the incident light to the blue color filter layer and a region of passage of the incident light to the green color filter layer exhibit higher light transmissivity to the incident light than a region of passage of the incident light to the red color filter layer. The color conversion layer preferably comprises a matrix resin and the at least one color conversion material dispersed in the matrix resin. The color filter preferably further comprises a gas barrier layer covering the color conversion layer.

Another aspect of the present invention provides an organic EL display that comprises a transparent substrate, plural types of color filter layers disposed on the transparent substrate, a color conversion layer containing at least one color conversion material and disposed in one-piece over the color filter layers, wherein at least one of the color conversion materials absorbs a wavelength region of incident light and emits light in a different wavelength region from the absorbed wavelength region, and a region in the color conversion layer of passage of the incident light towards one color filter layer exhibits higher light transmissivity to the incident light than regions in the color conversion layer of passage of the incident light towards the other color filter layers, a transparent first electrode disposed opposing the color filter layers across the color conversion layer, an organic EL layer containing at least an organic light emitting layer disposed opposing the color filter layers across the transparent first electrode, and a second electrode disposed opposing the transparent first electrode across the organic EL layer.

Preferably, the organic EL display comprises a color filter with color conversion function that includes the transparent substrate, the plurality types of color filter layers, and the color conversion layer. The organic EL display favorably comprises an organic EL device with color conversion function that includes the color conversion layer, the transparent first electrode, the organic EL layer, and the second electrode. The color conversion layer preferably contains at least two types of color conversion materials. The color conversion layer is favorably a film formed by means of an evaporation method. A thickness of the color conversion layer is preferably at most 2,000 nm.

Another aspect of the invention provides a method of producing a color filter with color conversion function. The method comprises a step of fabricating an intermediate color filter that comprises a transparent substrate, plural types of color filter layers disposed on the transparent substrate, and a color conversion layer containing at least one color conversion material and disposed over the color filter layers, wherein at least one of the color conversion materials absorbs a wavelength region of incident light and emits light in a different wavelength region from the absorbed wavelength region, and a step of photo-bleaching at least one color conversion material in a region in the color conversion layer of passage of an incident light towards one type of the color filter layers. Preferably, the step of photo-bleaching includes a process of irradiating electromagnetic wave onto the region of passage of the incident light in the intermediate color filter.

A color filter with color conversion function according to the present invention has distinctive advantages as a color filter for display, as described in further detail in the following. In a device according to the invention, the light emitted from an independently controllable light source at a position corresponding to one of the subpixels arranged in a matrix form is converted to light having a wider range of spectrum through the hue change by the color conversion layer. This inventive structure having only a single color conversion layer can convert the light in the blue to blue-green color range from a back light source, for example, to the light having a spectrum containing a component in the red color range. Therefore, the production process is simplified leading to cost reduction. As for high definition display, the color conversion layer is formed as one-piece without patterning, thereby avoiding the problems of reproducibility of shape and distortion of pattern.

The light passed through the color conversion layer enters the color filter of each subpixel. In the subpixel for blue to blue-green color, for example, a part of the color conversion layer corresponding to the color filter of the subpixel is made to have higher transmissivity to the light from the back light, which allows the blue to blue green color component contained in the back light can be more effectively utilized. On the other hand, in the subpixel for red color, for example, absorption of the light from the back light is enhanced to increase hue change in the color conversion layer providing the light having a spectrum containing abundant component in red color region. Therefore, brighter red color light is emitted at the red color subpixel.

### BRIEF DESCRIPTION OF THE DRAWINGS

The foregoing advantages and features of the invention will become apparent upon reference to the following detailed description and the accompanying drawings, of which:

FIG. 1 is a schematic sectional view of a structure of a color filter with color conversion function according to the first embodiment of the invention;

FIG. 2 is a schematic sectional view of an example of an organic EL display using a color filter with color conversion function produced by a production method according to the invention;

FIG. 3 is a schematic sectional view of another example of an organic EL display using a color filter with color conversion function produced by a production method according to the invention; and

FIG. 4 is a schematic sectional view of another example of an organic EL display according to the invention.

### DETAILED DESCRIPTION OF SPECIFIC EMBODIMENTS

Now, preferred embodiments according to the invention will be described in the following with reference to the accompanying drawings. The present invention, however, shall not be limited to the embodiments.

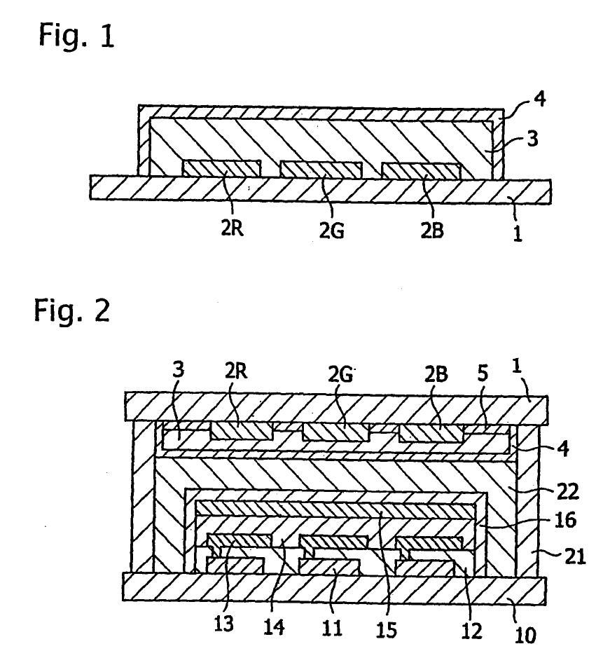

A color filter with color conversion function according to a first embodiment of the invention is a laminate comprising plural types of color filter layers 2, and color conversion layer 3 containing color conversion material (CCM) disposed over transparent substrate 1. FIG. 1 shows a case provided with three types of color filter layers (red color 2R, green color 2G, and blue color 2B). Color conversion layer 3 works as a layer to change the hue of the incident light from a light source. The color conversion material in color conversion layer 3 absorbs light including a part of the wavelength of the incident light and emits light including a wavelength range different from the absorbed wavelength range. The color conversion layer emits light that is a combination of the light including the wavelength range not absorbed by the color conversion material and the light emitted by the color conversion material, resulting in emission of light with different hue from the incident light. More specifically, color conversion layer 3 absorbs light of a part of the wavelength range of the incident light and emits light having a spectrum including the light in the wavelength range not substantially contained in the incident light. This feature of the invention converts light from color conversion layer 3 into light including a wide spectral range (for example, white light, the light containing all spectral regions of the three primary colors). In the specification of the invention, the wording “not substantially contained in the incident light” means “not existing in an intensity that affects the hue of the incident light.” For example, using incident light in the blue to blue-green color region, a part of the light in the wavelength range of blue color is converted to the light having a spectrum containing red color region by a color conversion material, to obtain light emission with a wider range of spectrum than incident light.

Transparent substrate 1 is necessarily transparent to the visible light (wavelength range from 400 nm to 700 nm), preferably to the light converted by color conversion layer 3. Transparent substrate 1 must withstand the conditions (solvent, temperature and so on) in the process of forming color conversion layer 3 and other layers that are formed as needed. The substrate should exhibit good dimensional stability. Preferred materials for transparent substrate 1 include glass and resins such as poly(ethylene terephthalate) and poly(methyl methacrylate). Particularly favorable are amino silicate glass, borosilicate glass, and blue plate glass.

Color filter layer 2 transmits only light in the desired wavelength range. Color filter layer 2 effectively cut off the light transmitted through color conversion layer 3 and is effective in obtaining light in the desired wave length region (hue) from the light that has undergone conversion of wavelength distribution in color conversion layer 3. Color filter layer 2 favorably contains a color conversion material and a photosensitive resin. A preferred color conversion material is selected from pigments that exhibit sufficient light stability. Preferred photosensitive resins include: (1) compositions obtained by polymerizing acrylic polyfunctional monomers or oligomers that contain acrolyl group or methacrolyl group using a photo-polymerization initiator, (2) compositions comprised of poly(vinyl cinnamate) and photo sensitizer, (3) compositions obtained by polymerizing direct chain or cyclic olefin using bisazide (nitrene is generated to crosslink the olefin), and (4) compositions obtained by polymerizing monomers containing epoxy groups using a photochemical oxidizing agent. Color filter layer 2 can be formed, for example, using a commercially available color filter material for liquid crystal devices (Color Mosaic produced by Fujifilm Arch Co., Ltd, for example). Thickness of a color filter for each color is preferably in the range of 1 to 1.5 μm. The word “a subpixel” is occasionally used in the same meaning as “a color filter layer,” in this specification.

Color conversion layer 3 contains at least one type of color conversion material. Color conversion layer 3 can further contain a matrix resin. Color conversion layer 3 generally has a flat surface. The color conversion layer is preferably formed in one-piece covering a plurality of color filter layers (not for individual subpixels, but for the whole surface). In this configuration, the color conversion layer works as a protective layer for the plural types of color filters. The color conversion material converts the wavelength distribution of the incident light and emits light having a spectrum containing a wavelength region that is substantially not included in the incident light. Preferably, the color conversion material converts the wavelength distribution of light in a blue to blue-green region and emits light having a spectrum containing red color region, which is transmitted through the red color filter layer 2R. Color conversion layer 3 can contain a plurality of color conversion materials to adjust the spectrum of wavelength provided by the color conversion layer. For example, the color conversion layer can contain a first color conversion material that converts the light in blue to blue-green color region to light having a spectrum containing green color region, and a second color conversion material that converts light having a spectrum containing the green color region as well as the blue to blue-green color region to the light having a spectrum containing red color region. This improves conversion efficiency of the wavelength distribution of the incident light.

In a device according to the invention, passage of light in the color conversion layer towards one color filter layer has a higher light transmissivity to the incident light than passages towards other color filter layers. That means a region of the color conversion layer is regionally highly transmissive to the backlight. The highly transmissive region of color conversion layer 3 performs little conversion (or practically no conversion) of wavelength distribution. Thus, the spectrum of the incident light can be used effectively. One specific color filter layer is intended to transmit practically the whole spectrum of the incident light without conversion of wavelength distribution in color conversion layer 3. The portion of the color conversion layer formed on the specific color filter layer is made to exhibit high transmissivity (or low absorbance) to reduce the degree of conversion of wavelength distribution, thereby effectively utilizing the spectrum of the incident light. The passage region for incident light means a partial region of the color conversion layer through which the incident light passes towards a specific color filter layer.

Another color filter layer is intended to transmit the light of the spectrum that is obtained by conversion of wavelength distribution in color conversion layer 3 and that is practically not contained in the incident light. The proportion of the color conversion layer formed on this color filter layer is made to exhibit low transmissivity (or high absorbance) to raise the degree of conversion of wavelength distribution, thereby intensifying the light spectrum through the color filter layer and providing high luminance.

For example, referring to FIG. 1, in order to obtain blue (B), green (G), and red (R) colors using the incident light including the blue to blue-green color region, the portions of the color conversion layer overlapping the blue color filter layer 2B and the green color filter layer 2G are preferably made to exhibit higher light transmissivity than the portion overlapping the red color filter layer 2R.

Color conversion layer 3 of the invention can be fabricated as follows. First, a coating liquid prepared by dissolving a color conversion material and a matrix resin as described later in an organic solvent and applied on transparent substrate 1 and color filters 2R, 2G, and 2B. Any application method known in the art can be employed including spin coating, roll coating, casing, dip coating, as long as it allows the top surface of color conversion layer 3 to be flat. Color conversion layer 3 also can be formed by evaporation, as described later in detail.

In the incident light passage in the resulting color conversion layer 3 of the intermediate color filter, at least a portion of at least one of the color conversion materials is photo-bleached, thereby enhancing transmissivity of the backlight in this portion of the color conversion layer. The transmissivity to the backlight in color conversion layer 3 can be changed by, for example, illuminating the color conversion material included in color conversion layer 3 with high energy light (electromagnetic wave) of ultraviolet light using a photo mask to partly decompose the color conversion material. The bleaching of a color conversion material in this specification means any mode of change in the color conversion material in which optical transmissivity to incident light of the color conversion material changes (preferably decreases), including the mode of change by decomposition or oxidation.

The photo-bleaching can be carried out using a light source of an ultraviolet lamp such as a low pressure mercury lamp, a metal halide lamp, or an excimer lamp. The wavelength of the light source is not limited to any special region with respect to the absorption wavelength of the color conversion material, but preferably contains a high energy range of about 400 nm or shorter, and can oxidize or decompose a part or whole of the color conversion material molecules. The intensity of illumination of the light source is preferably from 10 to 30 mW/cm² at a wavelength of 365 nm, and the illuminating time is desirably selected so that about one tenth of the color conversion material remains undecomposed. Illumination of light of 20 mW/cm² for 5 to 10 minutes results in the proportion of remained color conversion material of about 10%, although the proportion depends on the type and concentration of the color conversion material and the thickness of color conversion layer 3. Illumination of longer than the time in this range may promote decomposition of matrix resin and generate discoloration or a rough surface.

The mechanism of the change of light transmissivity due to ultraviolet light illumination has not been thoroughly revealed, and any theory shall not put restraints on the invention. Nevertheless, it is thought that the light absorption ability of the color conversion material to a backlight decreases or even disappears due to photochemical oxidation or photochemical decomposition by high energy light with a wavelength region below the absorption wavelength of the color conversion material, and that this may be the cause of the enhancement in transmissivity.

The relation between the wavelength of the incident light and the enhancement of transmissivity is not thoroughly understood. However, as shown below in detail with reference to embodiment examples, the fact of three primary color emission through the color conversion layer demonstrates that the illumination of ultraviolet light degrades the absorption ability to the light at least in the wavelength range of blue to blue-green color light, which would be originally absorbed by the color conversion dye.

Description was made above on a means to regionally change the transmissivity of color conversion layer 3 to a backlight, in which high energy light is illuminated through a photomask to regionally photo-bleach the color conversion material. However, it should be acknowledged that other means can produce the same effect. The transmissivity of color conversion layer 3 also can be changed by: (A) illuminating the whole surface with electromagnetic waves while varying illumination intensity regionally (for example, exposing to electromagnetic wave through a filter having regionally different transmissivity, such as a monochromatic negative photographic film, or scanning a micro light source varying intensity of emitting light); or (B) illuminating with electromagnetic waves while masking regionally, as described above. Regional exposure can be carried out by contact exposure using a photomask, or projection exposure (which can be partial exposure using light condensed by a lens or light generated by a micro light source; or using a photomask together here).

As mentioned previously, WO97/43874 and Japanese Patent Unexamined Publication No. 2001-131434 disclose photo-bleaching by illumination of electromagnetic waves. However, the photo-bleaching is conducted on fluorescent material doped in a light emitting layer in these documents, while in the present invention, photo-bleaching is carried out on fluorescent dye in a color conversion layer. Moreover, the effect is quite different between the photo-bleaching on a light emitting layer and the photo-bleaching on a color conversion layer.

The essential point of the technology disclosed in WO97/43874 and Japanese Patent Unexamined Publication No. 2001-131434 does not exist in the use of the change of optical transmissivity (degradation of optical absorption ability) of a color conversion material that is brought onto function failure, but in the control of energy transfer from excitons in the host material of an organic light emitting layer as described earlier. Therefore, sufficient separation is impossible when the absorption band of the dopant dye is in extreme proximity or overlapping, causing difficulty in dye selection. In addition, the light wavelength must be adjusted by inserting a filter in front of the illuminating light source.

In the present invention, without using control of the color of the light emitted from the dopant, the color conversion material of the color conversion layer is regionally brought onto function failure (a condition with degraded absorption ability) by illumination of electromagnetic waves (light), and enhanced transmissivity to the light emitted from the organic EL layer is exploited. It is therefore sufficient to irradiate by short wavelength light (a broad band light source that emits light in a wavelength region not longer than 400 nm is adequate) containing absorption wavelength of the color conversion material employed in the color conversion layer.

A color conversion material that absorbs light in blue to blue-green color region and emits light with a spectrum containing red color region can be selected from rhodamine dyestuffs such as rhodamine B, rhodamine 6G, rhodamine 3B, rhodamine 101, rhodamine 110, sulforhodamine, basic violet 11, and basic red 2; cyanine dye stuffs; pyridine dyestuffs such as 1-ethyl-2-[4-(p-dimethyaminophenyl)-1,3-butadienyl]-pyridinium perchlorate (pyridine 1); and oxazine dyestuffs.

A color conversion material that absorbs light in blue to blue-green color region and emits light with a spectrum containing green color region can be selected from coumarin dyestuffs such as 3-(2′-benzothiazolyl)-7-diethylamino-coumarin (coumarin 6), 3-(2′-benzoimidazolyl)-7-diethylamino-coumarin (coumarin 7), 3-(2′-N-methylbenzoimidazolyl)-7-diethylamino-coumarin (coumarin 30), 2,3,5,6-1H,4H-tetrahydro-8-trifluoromethyl quinolidine (9,9a,1-gh) coumarin (coumarin 153), a dyestuff in a class of coumarin dyestuff of basic yellow 51, and naphthalimide dyestuffs such as solvent yellow 11 and solvent yellow 116.

Various dyes (direct dyes, acid dyes, basic dyes, and disperse dyes) other than those mentioned above can also be used so long as it allows desired conversion of wavelength distribution.

A matrix resin useful in color conversion layer 3 can be selected from, in addition to the materials obtained by curing the photosensitive resins for the color filter layer mentioned above, thermoplastic resins including polycarbonate, polyester (such as poly(ethylene terephthalate)), poly(ether sulfone), poly(vinyl butyral), poly(phenylene ether), polyamide, poly(ether imide), norbornene resin, methacrylic resin, isobytylene-mareic anhydride copolymer resin, cyclic olefin resin, poly(vinyl chloride), vinyl chloride-vinyl acetate copolymer resin, alkyd resin, and aromatic sulfone amide resin; thermosetting resins including epoxy resin, phenolic resin, urethane resin, acrylic resin, vinyl ester resin, imide resin, urea resin, and melamine resin; and polymer hybrids containing polystylene, polyacrylonitrile, or polycarbonate and trifunctional or tetrafunctional alkoxysilane. A mixture of these resins can also be used for the matrix resin.

In the case of a color conversion layer including a matrix resin, a color conversion material is contained in the color conversion layer in a proportion of at least 0.2 micromol, preferably in the range of 1 to 20 micromol, more preferably in the range of 3 to 15 micromol with respect to 1 g of matrix resin. The thickness of color conversion layer 3 including a matrix resin is at least 5 μm, preferably in the range of 5 to 15 μm (a thickness in the region without a color filter, or a thickness at the top surface of a black mask in the case a black mask is provided). By setting the amount of contained color conversion material and the film thickness in the range defined above, the color-converted output light is obtained with desired intensity.

A color conversion layer can be practically composed of color conversion material alone, without using a matrix resin, by forming the color conversion layer by means of evaporation. When patterning is conducted with a line width less than the film thickness, problems may arise in reproducibility of the pattern shape or distortion of the pattern in the following steps, as mentioned previously. However, when the color conversion layer is formed by evaporation, a color conversion layer can be practically composed of color conversion material alone without using a matrix resin, and thus obtaining a thinner film.

A color conversion layer without a matrix resin preferably contains at least two types of color conversion materials. The color conversion layer preferably contains first and second color conversion materials in which the first color conversion material can convert the wavelength distribution of the incident light into a wavelength distribution that is acceptable by the second color conversion material. By this means, the first color conversion material, absorbing the incident light to the color conversion layer, transfers the energy of the incident light to the second color conversion material. The second color conversion material, accepting the energy from the first color conversion material, emits light with a spectrum different from that of the incident light. The first color conversion material is a color conversion material that absorbs the incident light to the color conversion layer, preferably light emitted by an organic EL device (preferably in blue to blue-green color), and transfers the absorbed energy to the second color conversion material. Consequently, the absorption spectrum of the first color conversion material favorably overlaps the emission spectrum of the organic EL device. More preferably, the absorption maximum of the first color conversion material coincides with the maximum of the emission spectrum of the organic EL device. The emission spectrum of the first color conversion material is desired to overlap the absorption spectrum of the second color conversion material. More preferably, the maximum of the emission spectrum of the first color conversion material coincides with the absorption maximum of the second color conversion material. Here, the wording “the maximum of a spectrum coincides with the maximum of another spectrum” means that a difference between the maxima of wavelength is within 10%, preferably within 5%.

When the concentration of a color conversion material is increased due to the decrease of film thickness, the efficiency may fall due to so-called concentration quenching. Nevertheless, a color conversion layer containing at least two types of color conversion materials allows the compatibility between a thin film thickness and high color conversion efficiency. While any theory shall not impose limitation on the invention, it is hypothesized that in an excited state generated by light absorption in the first color conversion material of the color conversion layer, energy transfer from the first color conversion material to the second color conversion material occurs more readily than energy transfer between the first color conversion materials. Therefore, almost all of the excitation energy of the first color conversion material can be considered to transfer to the second color conversion material without undergoing loss by transfer between the first color conversion materials (concentration quenching), and contribute to light emission of the second color conversion material. By controlling the concentration of the second color conversion material low enough to inhibit concentration quenching, the transferred excitation energy is effectively used for color conversion, thereby achieving light emission having a desired wavelength distribution. Thus, a color conversion layer of the invention allows the compatibility between a thin film thickness and high color conversion efficiency. In other words, the functions of absorption of incident light and conversion of wavelength distribution are separated, and the functions are borne by the first color conversion material and the second color conversion material, respectively. By this means, a high efficiency in color conversion can be favorably ensured without increasing thickness.

A multicolor light emitting organic EL device as formed using such a color conversion layer has little view angle dependence and hardly changes its hue with the passage of operation time or with variation of electric current in the device, maintaining stable light emitting performance for a long time. On the other hand, it is feared in a structure comprising light emitting layers corresponding to respective colors of emitting light that shift of color (change of hue) may occur due to continued running of electric current because degradation characteristics vary depending on the material for respective color emission.

Since absorption of the incident light and color conversion are carried out by different types of color conversion materials, the difference between the peak absorption wavelength of the incident light in the first color conversion material and the peak emission wavelength after color conversion by the second color conversion material can be greatly increased. Since the functions are separated, material selection is wider in each of the first color conversion material and the second color conversion material.

Preferred materials for the first color conversion material include coumarin dyes such as 3-(2′-benzothiazolyl)-7-diethylamino-coumarin (coumarin 6), 3-(2′-benzoimidazolyl)-7-diethylamino-coumarin (coumarin 7), and coumarin 135. Naphthalimide dyes such as solvent yellow 43 and solvent yellow 44 can also be used for the first color conversion material.

As described above, it is favorable that the emission spectrum of the first color conversion material and the absorption spectrum of the second color conversion material overlap each other, and it is more favorable that the maximum of the emission spectrum of the first color conversion material coincide with the absorption maximum of the second color conversion material. Consequently, the light emitted from the second color conversion material generally has a longer wavelength than the light absorbed by the first color conversion material. Preferred dyestuffs for the second color conversion material in the invention include cyanine dyes such as 4-dicyanomethylene-2-methyl-6-(p-dimethylamino styryl)-4H-pyran (DCM-1 (I)), DCM-2 (II), and DCJTB (III); 4,4-difluoro-1,3,5,7-tetraphenyl-4-bora-3a,4a-diaza-s-indacene (IV), Lumogene F Red, and Nile Red (V). Also useful are xanthene dye such as rhodamine B and rhodamine 6G, and pyridine dyes such as pyridine 1.

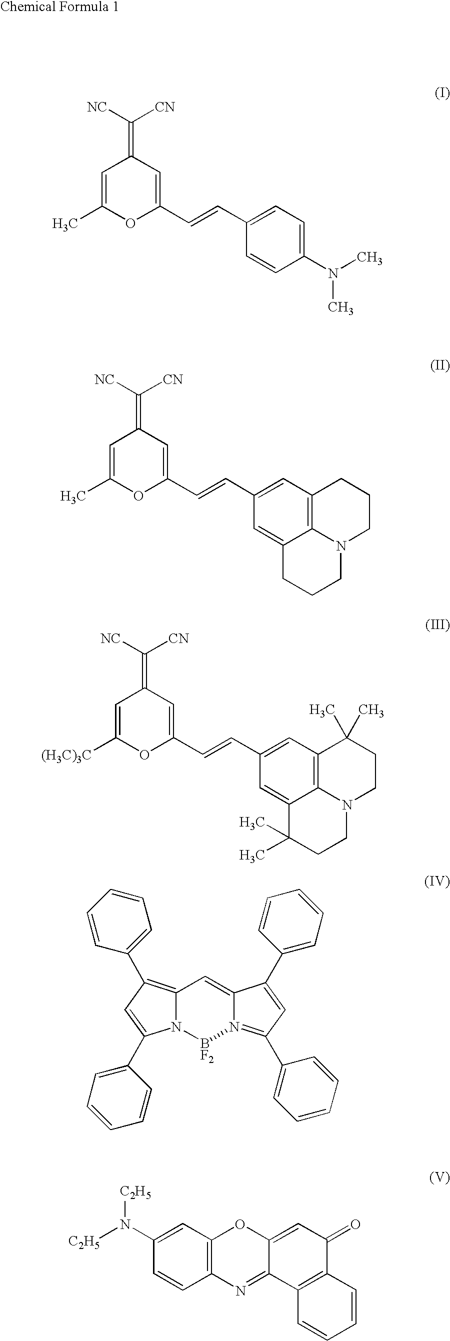

The first color conversion material preferably exists in the proportion of from 50 to 99.99 mol % with respect to the total number of molecules composing the color conversion layer. The first color conversion material contained in this concentration range sufficiently absorbs incident light to the color conversion layer and transfers the absorbed light energy to the second color conversion material.

It is the second color conversion material that emits light in this color conversion layer. So, it is desired that the second color conversion material not cause concentration quenching. If the second color conversion material causes concentration quenching, color conversion efficiency falls. The upper limit of concentration of the second color conversion material in a color conversion layer of the invention can vary depending on the types of the first and second color conversion materials under the condition that concentration quenching is adequately avoided. The lower limit of concentration of the second color conversion material can vary depending on the types of first and second color conversion material and the target of application under the condition that sufficient intensity of converted light is obtained. Preferred concentration of the second color conversion material in the color conversion layer of the invention generally at most 10 mol %, preferably in the range of 0.01 to 10 mol %, more preferably in the range of 0.1 to 5 mol %. The second color conversion material used in this concentration range appropriately prevents concentration quenching and favorably gives sufficient intensity of converted light.

A color conversion layer without a matrix resin preferably has a thickness at most 2,000 nm (2 μm), more preferably in the range of 100 to 2,000 nm, most preferably in the range of 200 to 1,000 nm. In the color conversion layer of the invention, the function to absorb the incident light is carried out by the first color conversion material, which composes most of the color conversion layer, so that such a thin layer can provide sufficient absorbance.

A color conversion layer without a matrix resin is preferably formed by means of evaporation (including resistance heating method and electron beam heating method). More preferably, the color conversion layer is formed by co-evaporation of a first color conversion material and a second color conversion material. By this technique, the second color conversion material is appropriately dispersed in the first color conversion material, and concentration quenching is adequately avoided. The co-evaporation can be carried out using a preliminary mixture that is prepared by mixing the first color conversion material and the second color conversion material in a predetermined ratio. Alternatively, the first color conversion material and the second color conversion material are arranged at different heating locations and separately heated to carry out the co-evaporation. When there is a large difference in some property (evaporation speed, vapor pressure or any other), the latter method is particularly effective. Fabrication of the color conversion layer by an evaporation method promotes effective use of material. The color conversion layer can be formed by, in addition to the evaporation method, a casting method, a spraying method, a printing method, or an inkjet method.

Between or around plural types of color filter layers 2, black mask 5 (see FIG. 2) that inhibits transmission of visible light can be optionally provided to enhance a contrast ratio. Black mask 5, which includes a black pigment or dye dispersed in a resin, can be formed of a commercially available black mask material for liquid crystals. In this embodiment, gas barrier layer 4 can be further provided covering color conversion layer 3. A material for gas barrier layer 4 is preferably selected from materials that exhibit high transmissivity to visible light (a transmittance at least 50% in the range of 400 to 700 nm), Tg of at least 100° C., a pencil hardness of 2H or harder, and don't degrade the functions of the color conversion layer 3. Preferred materials for forming gas barrier layer 4 can be selected from inorganic oxides or inorganic nitrides including SiOₓ, SiNₓ, SiNₓO_{y}, AlOₓ, TiOₓ, TaOₓ, and ZnOₓ.

Gas barrier layer 4 in the invention can be in the form of a single layer or in the form of a lamination structure consisting of plural layers formed of individual material. Gas barrier layer 4 of a lamination structure of plural layers can be formed by laminating a plurality of layers of the inorganic oxides or nitrides mentioned above. For the purpose of improving flatness of the surface, gas barrier layer 4 can be formed by laminating a layer of inorganic oxide or inorganic nitride and a layer of organic material. Useful materials include, for example, imide-modified silicone resin (Japanese Patent Unexamined Publication Nos. H05-134112, H07-218717, and H07-306311), inorganic compounds of metal (TiO₂, Al₂O₃, SiO₂ or the like) dispersed in acrylic resin, polyimide resin, or silicone resin (Japanese Patent Unexamined Publication Nos. H05-119306 and H07-104114), epoxy-modified acrylate resin, ultraviolet-light-setting resins of acrylate monomer/oligomer/polymer containing reactive vinyl group (Japanese Patent Unexamined Publication No. H07-48424), resist resin (Japanese Patent Unexamined Publication Nos. H08-279394, H06-300910, H07-128519, and H09-330793), inorganic compounds (that can be formed by a sol-gel method; Monthly Display, Vol. 3, No. 7, (1997) (in Japanese) and Japanese Patent Unexamined Publication No. H08-27934), and optically-setting and thermally-setting resins such as fluorine-containing resins (Japanese Patent Unexamined Publication Nos. H09-330793 and H05-36475).

Gas barrier layer 4 can be formed of these materials by means of any method known in the art selected from dry methods (including a sputtering method, an evaporation method, a CVD method and the like) and wet methods (a spin-coating method, a roll-coating method, a casing method, a dip-coating method and the like). A gas barrier layer 4, when provided, is desired as thin as possible in order to minimize view angle dependence (hue variation depending on viewing angle) as far as sufficient barrier performance against gasses (oxygen, moisture, vapor of organic solvent, and the like) is achieved.

Thus, a color filter with color conversion function is obtained in this embodiment which provides the three primary colors RGB necessary for a full color display. Accordingly, a multicolor display device can be formed by arranging a plurality of independently controllable light sources corresponding to positions in the color conversion layer. The matrix resin of color conversion layer 3 is not patterned, but is in an as-formed shape of one-piece. Therefore the problems of reproducibility and distortion of a pattern are avoided. Color conversion layer 3 in this embodiment can be formed covering the plural types of color filter layers 2 that are disposed under color conversion layer 3. As a result, color conversion layer 3 also works as a protective layer that protects color filter layers 2 against the impact of environment (moisture, oxygen and the like).

While this embodiment has been described on the case of forming color filter layers 2 for three primary colors of RGB, it will be acknowledged that the other colors can be used as well. Further, the color filters can be formed in two types or four or more types, preferably two to six types of color filter layers can be formed, if desired.

The color filter with color conversion function of this embodiment is particularly effective in combination with a light source that is independently controllable and allows arrangement with high definition and in matrix alignment. The light source is positioned on the side of color conversion layer 3 of the color filter. The color filter can be combined with, for example, a light bulb with a liquid crystal shutter, an EL device, a plasma light emitting device, or a light emitting diode (LED), preferably an EL device, more preferably an organic EL device, most preferably an organic EL device that emits light in the blue to blue-green color region. A color filter with color conversion function of this embodiment can be laminated with an organic EL device formed on another substrate, to produce an organic EL display of a top emission configuration. Or an organic EL device can be formed over a color filter with color conversion function of this embodiment, to form a display of a bottom emission configuration.

An organic EL display of a second embodiment according to the present invention is a combination of a color filter with color conversion function of the first embodiment and an organic EL device. FIG. 2 shows an organic EL display of a top emission configuration formed by lamination of a color filter with color conversion function and an organic EL device. An active matrix type organic EL device is formed by providing planarizing film 12, second electrode 13, organic EL layer 14, first electrode 15, and passivation layer 16 on substrate 10 having preliminarily formed switching elements of TFTs 11. Second electrode 13 is divided into plural parts (like islands) each corresponding to a subpixel and connecting to one TFT 11. Second electrode 13 is preferably a reflective electrode. First electrode 15 can be formed as one uniform film over a whole surface. First electrode 15 is a transparent electrode. The layers to form the organic EL device can be formed employing materials and methods known in the art.

On transparent substrate 1 color filter layers 2B, 2G, and 2R for blue, green, and red colors, and color conversion layer 3 are formed. Optional components can be formed including black mask 5 between and around color filter layers 3, and gas barrier layer 4 covering color filter layers 2, color conversion layer 3, and black mask 5.

The organic EL device and the color conversion filter are laminated aligning each other and forming filler material layer 22 (optionally provided) between them. Finally, peripheral sealing layer 21 (an adhesive) is used to seal around the peripheral region, to obtain an organic EL display. While FIG. 2 illustrates an active matrix-driving type display, a passive matrix-driving type organic EL device can of course be employed. In that case, preferably, second electrode 13 is consists of plural stripe-shaped electrode elements extending in a first direction and first electrode 15 consists of plural stripe-shaped electrode elements extending in a second direction, arranging the electrode elements of second electrode 13 and the electrode elements of first electrode 15 crossing each other, preferably orthogonally.

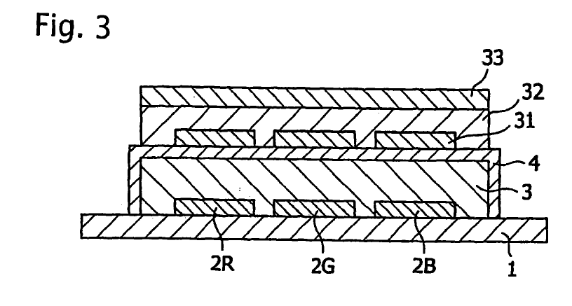

FIG. 3 shows an example of organic EL display of third embodiment according to the present invention. The organic EL display is a bottom emission type organic EL display having an organic EL device directly formed on a color filter with color conversion function of the first embodiment. The color filter with color conversion function shown in FIG. 3 comprises blue color filter layer 2B, green color filter layer 2G, and red color filter layer 2R that are formed on transparent substrate 1, color conversion layer 3, and gas barrier layer 4 covering them. The color filter with color conversion function can optionally comprise black mask 5 disposed between the color filter layers and around the color filter layers (not shown in FIG. 3). The organic EL device of FIG. 3 is a passive matrix driving type and comprises first electrode 31 consisting of plural stripe-shaped electrode elements extending in a first direction, and second electrode 33 consisting of plural stripe-shaped electrode elements extending in a second direction. The first direction and the second direction preferably cross each other, more preferably crossing orthogonally. In the structure of FIG. 3, first electrode 31 is transparent and second electrode 33 is reflective.

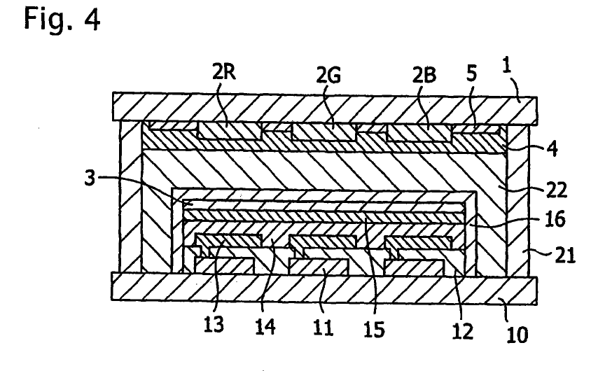

FIG. 4 shows an organic EL display of a fourth embodiment according to the present invention. The organic EL display is of a top emission configuration, and a color conversion layer and an organic EL device are combined in a one body. The organic EL display of the fourth embodiment comprises a color filter that has transparent substrate 1 and a plurality of color filter layers 2R, 2G, and 2B, and an organic EL device that has color conversion layer 3, transparent first electrode 15, organic EL layer 14, and second electrode 13.

The color filter has transparent substrate 1 and a plurality of color filter layers 2R, 2G, and 2B disposed on the transparent substrate. The color filter can further comprise gas barrier layer 4. The color filter can further comprise black mask 5.

The organic EL device comprises color conversion layer 3, transparent first electrode 15, organic EL layer 14, and second electrode 13. The color conversion layer is disposed on the whole surface of the first electrode. When the organic EL device and the color filter are combined, a passage of the incident light in the color conversion layer towards one color filter layer has a higher light transmissivity to the incident light than passages towards other color filter layers, as described earlier. The organic EL device can further comprise TFTs 11, planarizing film 12, and passivation layer 16. The organic EL device preferably comprises substrate 10, a plurality of TFTs 11 disposed on the substrate, planarizing film 12 disposed on the TFTs, second electrode 13 consisting of a plurality of electrode elements each connecting to one of the TFTs and disposed on the planarizing film, organic EL layer 14 disposed on the second electrode, transparent first electrode 15 disposed on the organic EL layer, color conversion layer 3 disposed on the transparent first electrode, and passivation layer 16. While the above description is made for an active matrix-driving type display, a passive matrix-driving type organic EL device can, of course, be employed.

The color conversion layer can be formed by a wet process or a dry process such as evaporation. In the case employing an organic EL device of a passive matrix-driving type in which the transparent first electrode has a stripe shape, an insulative protective layer is preferably provided on the transparent first electrode and then the color conversion layer is formed. This is for the purpose of protecting the organic EL layer against chemical agents used in a wet process and for the purpose of protecting color conversion materials against bleaching treatment (using UV light, for example). When an organic EL device of an active matrix-driving type is used and a transparent first electrode is formed on the whole surface of the organic EL layer, the transparent first electrode works as a protective layer for the organic EL layer (against both the chemical agents and the bleaching treatment), and an insulative protective layer need not be provided any more. Nevertheless, since the transparent first electrode normally has a very thin thickness of 100 to 200 nm, an insulative protective layer preferably is formed to protect the organic EL film against chemical agents in the wet process and then form a color conversion layer on the protective layer. The insulative protective layer can be composed of an inorganic film of SiNₓ, SiON or the like. Thickness of the insulative protective layer can be 300 nm, for example.

The organic EL layer (14, 32) emits light in the near ultraviolet to visible light region, preferably light in the blue to blue-green color region. The emitted light enters into the color conversion layer and converted to a wavelength distribution of a visible light in a desired color region. The organic EL layer (14, 32) comprises at least an organic light emitting layer, and as necessary, a hole injection layer, a hole transport layer, an electron transport layer, and an electron injection layer. A specific layer structure selected from the following can be employed.
(1) Organic light emitting layer
(2) Hole injection layer/Organic light emitting layer
(3) Organic light emitting layer/Electron injection layer
(4) Hole injection layer/Organic light emitting layer/Electron injection layer
(5) Hole injection layer/Hole transport layer/Organic light emitting layer/Electron injection layer
(6) Hole injection layer/Hole transport layer/Organic light emitting layer/Electron transport layer/Electron injection layer
   Here, an anode is connected to an organic light emitting layer or a hole injection layer, and a cathode is connected to an organic light emitting layer or an electron injection layer.

Materials of the above-mentioned layers can be selected from known materials. To obtain the light emission in blue to blue green color, the organic light emitting layer contains for example, a fluorescent brightening agent such as benzothiazole, benzoimidazole, or benzoxazole, metal chelate oxonium compound, styrylbenzene compound, aromatic dimethylidine compound. The hole injection layer can be composed of a phthalocyanine compound such as copper phthalocyanine, or a triphenylamine derivative such as m-MTDATA, for example. The hole transport layer can be composed of a biphenylamine derivative such as TPD or α-NPD. The electron transport layer can be composed of an oxadiazole derivative such as PBD, a triazole derivative, or a triazine derivative. The electron injection layer can be composed of an aluminum quinolinol complex. In addition, alkali metal, alkaline earth metal, and an alloy containing these metals, and alkali metal fluoride can also be used for the electron injection layer.

A transparent electrode can be formed by laminating a conductive metal oxide selected from SnO₂, In₂O₃, ITO, IZO, and ZnO:Al by means of a sputtering method. The transparent electrode preferably exhibits a transmissivity of at least 50%, more preferably at least 85% to light in the wavelength range of 400 to 800 nm. A reflective electrode can be formed by laminating a high reflectivity metal, an amorphous alloy, or a microcrystalline alloy by means of an evaporation method or a sputtering method. The high reflectivity metal can be selected from Al, Ag, Mo, W, Ni, and Cr. The high reflectivity amorphous alloy can be selected from NiP, NiB, CrP, and CrB. The high reflectivity microcrystalline alloy can be NiAl, for example. A material for the transparent electrode can also be selected from other alloys containing the above-mentioned high reflectivity metals, for example, Mg—Ag alloy.

In an organic EL display having the structure as described above, fabrication only a single layer color conversion layer 3 allows the light in blue to blue-green color region (the light having a spectrum that does not contain red color region practically) emitted by a light source that is an organic EL device to be converted into light having a spectrum containing abundant red color region. Therefore, cost reduction can be achieved owing to simplification of the process. In the subpixels for blue to blue-green color region, the light transmission rate to the backlight is made high in the regions overlapping the color filter layers for the color, thereby effectively utilizing the component of the blue to blue-green color region contained in the backlight. On the other hand, in the red color subpixels, the light transmission rate to the backlight is decreased, or absorption rate is relatively increased. As a result, the hue change in the color conversion layer is promoted, and thus, light with a spectrum abundantly containing red color region is obtained. Therefore, the red color subpixel emits red color light with higher brightness.

### EXAMPLES

Some specific embodiment examples according to the invention will be described in the following with reference to accompanying drawings. However, the present invention shall not be limited to the examples.

### Example 1

On a transparent substrate (a Corning 1737 glass substrate), a black mask and color filter layers were fabricated by a photolithography method using black mask material (Color Mosaic CK-7000, a product of Fujifilm Arch Co., Ltd.), blue filter material (Color Mosaic CB-7001, a product of Fujifilm Arch Co., Ltd.), green filter material (Color Mosaic CG-7001, a product of Fujifilm Arch Co., Ltd.), and red filter material (Color Mosaic CR-7001, a product of Fujifilm Arch Co., Ltd.).

Dimensions of each subpixel were 300 μm×100 μm. A gap between adjacent subpixels (which was the region where the black mask was formed) was 30 μm in the longitudinal direction and 10 μm in the transverse direction; the subpixels were arranged so that a combination of subpixels for blue, green and red colors constituted one pixel. A total of 2,500 pixels were formed arranging 50 pixels in the longitudinal direction and 50 pixels in the transverse direction. The thickness of the color filter layers was 1.5 μm and the thickness of the black mask was 1 μm.

A coating liquid was prepared by adding 0.05 g of coumarin 6 and 0.04 g of rhodamine B into 25 g of photoresist V259PAP5 (a product of Nippon Steel Chemical Co., Ltd.). The coating liquid was applied on the color filter layers and the black mask to obtain a color conversion layer 5 μm thick (a thickness at the top of the black mask).

Here, UV light was irradiated for 8 minutes on the region of the color conversion layer overlapping the blue color and green color filters while intercepting the light to the region of the color conversion layer overlapping the red color filter with a photomask, using an ultraviolet light irradiation apparatus equipped with a low pressure mercury lamp emitting light at 365 nm with illumination intensity of 20 mW/cm².

Then, a gas barrier layer was formed of a SiO₂ film 0.5 μm thick covering the color conversion layer by means of a sputtering method, to obtain a color filter with color conversion function. The sputtering apparatus was an RF planar magnetron type apparatus, the target was SiO₂, and the sputtering gas was argon. The substrate temperature in the process of forming the SiO₂ film was set at 80° C.

On another glass substrate, a reflective electrode (anode) composed of aluminum film 500 nm thick and ITO film 100 nm thick was formed by means of a sputtering method and a photolithography method. The reflective electrode has a stripe pattern extending in the longitudinal direction with each stripe width of 105 μm and a pitch of 110 μm (a gap between adjacent stripes of 5 μm).

Then, the substrate having the reflective electrode formed thereon was installed in a resistance heating evaporation apparatus at a pressure of 10⁻⁴ Pa in the vacuum vessel, and a hole injection layer of CuPc 100 nm thick, a hole transport layer of α-NPD 20 nm thick, a light emitting layer of DPVBi 30 nm thick, and an electron injection layer of Alq 20 nm thick were sequentially laminated. Thus, an organic EL layer was formed.

Then, a transparent electrode was laminated on the organic EL layer using a mask, the transparent electrode being composed of Mg/Ag film (weight ratio of 10/1) 10 nm thick and ITO film 10 nm thick. The transparent electrode had a stripe pattern extending in the transverse direction, with a stripe width of 300 μm and a pitch of 330 μm (a gap between adjacent stripes of 30 μm). Finally, a passivation layer composed of SiO₂ having a thickness of 500 nm was formed which covered the structure including the transparent electrode and the layers below, to obtain an organic EL device.

The color filter with color conversion function and the organic EL device were sent into a glove box controlled within 1 ppm of moisture and 1 ppm of oxygen. Ultraviolet light-setting adhesive (30Y-437, a product of Three Bond Co., Ltd.) containing dispersed beads of 6 μm diameter was applied around the transparent substrate of the color filter with color conversion function using a dispenser robot to form a peripheral sealing layer. The color filter and the organic EL device were aligned and adhered to form an assembly. Subsequently, ultraviolet light with intensity of 100 mW/cm² was illuminated for 30 sec to cure the peripheral sealing layer. Thus, an organic EL display of Example 1 was produced.

### Comparative Example 1

An organic EL display of Comparative Example 1 was produced in the same manner as in Example 1 except that the color conversion layer did not undergo the ultraviolet light illumination.

Light emitting characteristics were measured on the thus produced organic EL displays of Example 1 and Comparative Example 1. Specifically, measurements were made on chromaticity when the whole pixels were lit (the case W) and chromaticity and relative brightness (relative value to the case W being set equal to 100) when subpixel for each color (R, G, B) alone was lit. The results are given in Table 1.

TABLE 1
Relative brightness and chromaticity value of organic EL displays
using a color filter with color conversion function

| | Example 1 | | | Comparative Example 1 | | |
|---|---|---|---|---|---|---|
| | relative | | | relative | | |
| case | brightness | CIE-x | CIE-y | brightness | CIE-x | CIE-y |
| W | 100 | 0.32 | 0.30 | 69 | 0.40 | 0.30 |
| R | 26 | 0.62 | 0.36 | 26 | 0.62 | 0.36 |
| G | 36 | 0.25 | 0.63 | 23 | 0.25 | 0.63 |
| B | 38 | 0.12 | 0.23 | 20 | 0.12 | 0.23 |

These results show that ultraviolet light irradiation onto the region of color conversion layer corresponding to blue and green color subpixels increased the quantity of light transmitting through the blue and green filters and significantly improved the color balance and brightness as compared with a non-irradiated device.

### Example 2

An organic EL display of Example 2 was produced in the same manner as in Example 1 except that the color conversion layer was fabricated not by a wet process, but rather by an evaporation process.

The color conversion layer was fabricated as follows. The color conversion layer was composed of coumarin 6 and DCM-2. The color conversion layer was formed to a thickness of 200 nm by means of co-evaporation in which the coumarin 6 and DCM-2 were heated in each separate crucible within an evaporation apparatus. Temperatures of heating the crucibles were controlled so as to hold an evaporation speed of 0.3 nm/s for coumarin 6 and an evaporation speed of 0.005 nm/s for DCM-2. In this Example 2, the content of DCM-2 in the color conversion layer was 2 mol % with respect to total number of molecules in the color conversion layer (total molar number of whole color conversion materials in this case), which means the molar ratio of coumarin 6 to DCM-2 was 49 to 1. Irradiation of UV light onto the color conversion layer was carried out in the same manner as in Example 1.

### Example 3

An organic EL display of Example 3 was produced in the same manner as in Example 1 except that a gas barrier layer was formed on a color filter without forming a color conversion layer, and a color conversion layer was formed on a transparent electrode by evaporation and UV light was irradiated before covering a transparent electrode with a passivation layer. Deposition of the color conversion layer by evaporation and subsequent UV light irradiation onto the color conversion layer were conducted in the same manner as in Example 2.

The relative values of brightness measured in the same electric current condition as in Example 1 were 100 for the organic EL display of Example 2 and 110 for the organic EL display of Example 3 with respect to the brightness value of 100 in the case W in the organic EL display of Example 1 in which whole pixels were lit.

Thus, a color filter with a color conversion function, a method for producing the color filter, and an organic EL display have been described according to the present invention. Many modifications and variations may be made to the techniques and structures described and illustrated herein without departing from the spirit and scope of the invention. Accordingly, it should be understood that the devices and methods described herein are illustrative only and are not limiting upon the scope of the invention.

### DESCRIPTION OF SYMBOLS

1: transparent substrate

2R, 2G, 2B: color filter layer (red color, green color, and blue color)

3: color conversion layer

4: gas barrier layer

5: black mask

10: substrate

11: TFT

12: planarizing film

13, 33: second electrode (reflective electrode)

14, 32: organic EL layer

15, 31: first electrode (transparent electrode)

16: passivation layer

21: peripheral sealing layer

22 filler material layer

What is claimed is:

1. A color filter with color conversion function comprising:
a transparent substrate;
plural types of color filter layers disposed on the transparent substrate; and
a color conversion layer containing at least one color conversion material and disposed in one-piece over the color filter layers;
wherein at least one of the color conversion materials absorbs a wavelength region of incident light and emits light in a different wavelength region from the absorbed wavelength region, and
a region in the color conversion layer of passage of the incident light towards one color filter layer exhibits higher light transmissivity to the incident light than other regions in the color conversion layer of passage of the incident light towards the other color filter layers.

2. The color filter according to claim 1, wherein at least a portion of the color conversion materials in the region of passage of incident light exhibiting higher light transmissivity is photo-bleached.

3. The color filter according to claim 1, wherein the color conversion layer is formed in one-piece covering the color filter layers.

4. The color filter according to claim 1, wherein the incident light to the color conversion layer is light in a blue to blue-green color region, and at least one of the color conversion materials emits light having a spectrum containing a red color region.

5. The color filter according to claim 4, wherein the plural types of color filter layers are a red color filter layer, a green color filter layer, and a blue color filter layer, and a region of passage of the incident light to the blue color filter layer and a region of passage of the incident light to the green color filter layer exhibit higher light transmissivity to the incident light than a region of passage of the incident light to the red color filter layer.

6. The color filter according to claim 1, wherein the color conversion layer comprises a matrix resin and the at least one color conversion material dispersed in the matrix resin.

7. The color filter according to claim 1, further comprising a gas barrier layer covering the color conversion layer.

8. An organic EL display comprising:
a transparent substrate;
plural types of color filter layers disposed on the transparent substrate;
a color conversion layer containing at least one color conversion material and disposed in one-piece over the color filter layers, wherein at least one of the color conversion materials absorbs a wavelength region of incident light and emits light in different wavelength region from the absorbed wavelength region, and a region in the color conversion layer of passage of the incident light towards one color filter layer exhibits higher light transmissivity to the incident light than other regions in the color conversion layer of passage of the incident light towards the other color filter layers;
a transparent first electrode disposed opposite the color filter layers across the color conversion layer;
an organic EL layer containing at least an organic light emitting layer disposed opposite the color conversion layers across the transparent first electrode; and
a second electrode disposed opposite the transparent first electrode across the organic EL layer.

9. The organic EL display according to claim 8, comprising a color filter with color conversion function that includes the transparent substrate, the plurality types of color filter layers, and the color conversion layer.

10. The organic EL display according to claim 8, comprising an organic EL device with color conversion function that includes the color conversion layer, the transparent first electrode, the organic EL layer, and the second electrode.

11. The organic EL display according to claim 8, wherein the color conversion layer contains at least two types of color conversion materials.

12. The organic EL display according to claim 8, wherein the color conversion layer is a film formed by means of an evaporation method.

13. The organic EL display according to claim 8, wherein a thickness of the color conversion layer is at most 2,000 nm.

14. A method of producing a color filter with color conversion function comprising:
fabricating an intermediate color filter that comprises a transparent substrate, plural types of color filter layers disposed on the transparent substrate, and a color conversion layer containing at least one color conversion material and disposed over the color filter layers, wherein at least one of the color conversion materials absorbs a wavelength region of incident light and emits light in different wavelength region from the absorbed wavelength region; and
photo-bleaching at least one color conversion material in a region in the color conversion layer of passage of an incident light towards one type of the color filter layers.

15. The method according to claim 14, wherein the photo-bleaching includes a process of irradiating electromagnetic wave onto the region of passage of the incident light in the intermediate color filter.
